(19) United States
(12) Patent Application Publication
(10) Pub. No.: US 2021/0399524 A1
(43) Pub. Date: Dec. 23, 2021

(54) VERTICAL CAVITY SURFACE EMITTING LASER AND METHOD OF PRODUCING SAME

(71) Applicant: TRUMPF Photonic Components GmbH, Ulm (DE)

(72) Inventors: Sven Bader, Ulm (DE); Ulrich Weichmann, Aachen (DE)

(21) Appl. No.: 17/344,984

(22) Filed: Jun. 11, 2021

(30) Foreign Application Priority Data
Jun. 18, 2020 (EP) 20180755.9

(51) Int. Cl. H01S 5/183; H01S 5/042; H01S 5/026; H01S 5/227

(52) U.S. Cl. CPC H01S 5/18311; H01S 5/18377; H01S 5/2275; H01S 5/0421; H01S 5/0262; H01S 5/18344

(57) ABSTRACT

A Vertical Cavity Surface Emitting Laser (VCSEL) includes a layer stack of semiconductor layers having a first layer sub-stack forming a mesa, and a second layer sub-stack adjacent to the mesa in a stacking direction. Layers of the second layer sub-stack extend beyond layers of the first sub-stack in a direction perpendicular to the stacking direction. The semiconductor layers of the layer stack form an optical resonator having a first mirror, a second mirror, an active region between the first and second mirrors for laser light generation, and an oxide aperture layer forming a current aperture. The oxide aperture layer is made from Al₁₋ₓGaₓAs with 0≤x≤0.05. The oxide aperture layer is a last layer of the mesa and immediately adjacent to a first layer of the second layer sub-stack. A first layer of the second layer sub-stack is a contact layer.

### CROSS REFERENCE TO RELATED APPLICATIONS

This application claims benefit to European Patent Application No. EP 20180755.9, filed on Jun. 18, 2020, which is hereby incorporated by reference herein.

### FIELD

The present disclosure relates to a Vertical Cavity Surface Emitting Laser (VCSEL). The present disclosure further relates to a method of producing a VCSEL.

### BACKGROUND

VCSELs are a type of semiconductor laser diodes with laser beam emission perpendicular to the top or bottom surface. Typically, a VCSEL comprises a layer stack of semiconductor layers. Some or all of the semiconductor layers of the layer stack form an optical resonator comprising a first mirror, a second mirror and an active region between the first and second mirrors. The mirrors may be configured as distributed Bragg reflector (DBR) mirrors. DBR-mirrors typically comprise layers with alternating high and low refractive indices. In common VCSELs, the first and second mirrors comprise p-type and n-type doped materials, forming a diode junction. In other conventional configurations, the p-type and n-type regions may be embedded between the mirrors. The active region may comprise one or more quantum wells for laser light generation. The layer stack of semiconductor layers is typically grown on a wafer or substrate by epitaxial methods.

Common VCSELs usually include an epitaxially grown high aluminum content AlGaAs layer, respectively AlAs layer in close vicinity of the active region. During a wet-thermal oxidation process, this layer turns partly from the edge to the center of the layer into an isolating AlₓO_{y} material. The oxidation process serves to integrate an oxide aperture into the VCSEL, in order to raise the current density very close to the active pn-junction and to provide optical guiding for the laser mode. Current confinement may be essential to reach high current densities which will decrease the threshold current for lasing and ensure highly efficient devices. Further functions of the AlAs-layer—besides current and optical confinement—have not been expected in the past.

Some conventional VCSELs comprise an intracavity contact, as disclosed in U.S. Pat. No. 6,026,108 A1. When making an intracavity contact with good yield, extreme tolerances in the etching process or a thick epitaxial layer are required, which however leads to high absorption losses of the VCSEL.

### SUMMARY

In an embodiment, the present disclosure provides a Vertical Cavity Surface Emitting Laser (VCSEL). The VCSEL includes a layer stack of semiconductor layers having a first layer sub-stack forming a mesa, and a second layer sub-stack adjacent to the mesa in a stacking direction of the layer stack. Layers of the second layer sub-stack extend beyond layers of the first sub-stack in a direction perpendicular to the stacking direction. The semiconductor layers of the layer stack form an optical resonator having a first mirror, a second mirror, an active region between the first and second mirrors for laser light generation, and an oxide aperture layer forming a current aperture. The oxide aperture layer is made from Al₁₋ₓGaₓAs with 0≤x≤0.05. The oxide aperture layer is a last layer of the mesa and immediately adjacent to a first layer of the second layer sub-stack. A first layer of the second layer sub-stack is a contact layer.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 schematically shows a sketch of an embodiment of a VCSEL;

FIG. 2 shows a flow chart of a method of producing a VCSEL;

FIG. 3 shows a pre-stage of the VCSEL in FIG. 1 in a stage of the method of producing the VCSEL;

FIG. 4 shows the pre-stage of the VCSEL in a further stage of the method of producing the VCSEL;

FIG. 5 shows the pre-stage of the VCSEL in a further stage of the method of producing the VCSEL; and

FIG. 6 shows the pre-stage of the VCSEL in a further stage of the method of producing the VCSEL.

### DETAILED DESCRIPTION

The present disclosure provides a VCSEL which with an intracavity contact, and which can be produced with high yield without requiring excessive tolerances in the etching process or a thick epitaxial layer.

According to a first aspect, a Vertical Cavity Surface Emitting Laser (VCSEL) is provided. The VCSEL comprises a layer stack of semiconductor layers. The layer stack comprises a first layer sub-stack forming a mesa, and a second layer sub-stack adjacent to the mesa in stacking direction of the layer stack. The layers of the second layer sub-stack extend beyond the layers of the first sub-stack in direction perpendicular to the stacking direction. The semiconductor layers of the layer stack forming an optical resonator having a first mirror, a second mirror, an active region between the first and second mirrors for laser light generation, and an oxide aperture layer forming a current aperture. The oxide aperture layer is made from Al₁₋ₓGaₓAs with 0≤x≤0.05. The oxide aperture layer is the last layer of the mesa and immediately adjacent to a first layer of the second layer sub-stack, wherein the first layer of the second layer sub-stack is a contact layer.

In the following description, the Al₁₋ₓGaₓAs layer is briefly referred to as AlAs layer. The term ‘AlAs layer’ as used herein also includes an Al₁₋ₓGaₓAs-layer with 0<x≤0.05.

The VCSEL according to the disclosure allows for making an intracavity contact with high yield without requiring excessive tolerances in the etching process or a thick epitaxial layer. This advantage is achieved by an AlAs layer arranged as the last layer or the lowermost layer of the mesa, when seen from top of the mesa to the bottom of the mesa. Such a position of an AlAs-layer provides a dual-functionality of the AlAs-layer. A first function of the AlAs-layer is that it can be oxidized to provide the oxide aperture for current and optical confinement, as it is the case with conventional VCSELs. A second advantageous function of this AlAs-layer which has not been expected heretofore is that it can also be used as an etch-stop layer in the etching process of forming the mesa. The AlAs-etch-stop layer ensures a precise control of the etch depth, which is essential to target the contact layer immediately adjacent, or, when seen from top to bottom of the mesa, immediately below the AlAs-layer. An advantage here is that the contact layer immediately adjacent to the AlAs-layer can be made very thin without the risk that such a thin layer is removed in part or completely by the etching process. The contact layer may be used for providing an ohmic contact thereon. Thus, an intracavity contact can be easily formed in the VCSEL with high yield and without a thick epitaxial layer. As a further advantage, the absorption losses of the VCSEL are reduced in comparison with conventional VCSELs having an intracavity contact.

Preferentially, the contact layer may be arranged in a node of a standing wave field of generated laser light in the optical resonator.

A position of the contact layer in a node of a standing wave field of laser light in the optical resonator has the advantage that absorption losses by the contact layer are further reduced, in particular if the contact layer is highly doped.

Preferentially, the contact layer may have a doping concentration sufficient for ohmic behavior of the contact layer.

The doping concentration of the contact layer may be at least 6×10¹⁸ cm⁻³. The contact layer may be a doped GaAs-Layer.

Preferentially, the doping concentration in the contact layer may gradually decrease in thickness direction of the contact layer from a side facing the oxide aperture layer to the opposite side, or the doping concentration may gradually decrease from the contact layer to an adjacent layer on a side of the contact layer facing away from the oxide aperture layer.

These measures advantageously increase the lateral mobility of the carriers and lead to an improved conductivity of the contact layer.

Further preferentially, the contact layer may have a thickness of at least 10 nm. The thickness of the contact layer may be at least 15 nm, for example about 20 nm.

Providing the contact layer with a very small thickness advantageously reduces absorption of generated laser light by the contact layer. The smaller the thickness, the lower the absorption losses.

The subject matter of the present disclosure can be used in all standard VCSEL structures. However, the subject matter of the present disclosure is most useful in three-port lasers, as for example in VCSELs with integrated photodiode (ViPs). The subject matter of the present disclosure can find implementation in three-port devices, like an npn- or pnp-ViP.

Further preferentially, the contact layer may be a p-doped contact layer. The dopant may be carbon (C), zinc (Zn), or any other suitable dopant or a combination thereof in case of a p-contact layer, with a high dopant level of e.g. at least 6×10¹⁸ cm⁻³. The subject matter of the present disclosure is particularly suitable for configuration of the VCSEL as an npn-three-port device.

The VCSEL may comprise a photodiode having an intrinsic absorption region integrated into one of the first and second mirrors. Thus, the VCSEL may be a ViP with the advantageous integration of the absorption region of the photodiode into one of the first and second mirrors.

The first and second mirrors of the VCSEL may be configured as distributed Bragg reflectors (DBRs). The first and second mirrors may be built up by a plurality of pairs of layers with alternating high and low refractive indices. The second mirror may have a first portion facing the contact layer, which is a p-doped region of the layer stack, and a second portion facing away from the contact layer, which is an n-doped region of the layer stack, wherein the intrinsic absorption region of the photodiode is arranged between the first and second portions of the second mirror. The first mirror may be an n-doped region of the layer stack.

In these configurations, the VCSEL may be advantageously configured as an npn-ViP. In comparison with conventional ViPs having a pnpn-configuration, the npn-configuration has the advantage that one of the three pn-junctions is dispensed with. Thus, an unnecessary parasitic diode integrated into the device can be omitted. The voltage drop to forward bias the parasitic diode is no longer required and, thus, the photodiode bias voltage is reduced when one of three pn-junctions of the conventional ViP is removed. Further, the epitaxial growth of the npn-ViP becomes simplified and the risk to build up an eventually integrated phototransistor structure with break-through scenarios is reduced.

In a further configuration, at least one mirror layer pair of the second mirror may be arranged between the active region and the oxide aperture layer.

In this configuration, the dual-functional AlAs-layer is positioned more distant from the active region, whereby the efficiency of the current confinement would drop, however the optical guiding, too. This leads to a smaller numerical aperture (NA), which is beneficial in ViPs. For example, one to five mirror pairs, e.g. p-mirror pairs, may be arranged between the AlAs-layer and the active region.

According to a second aspect, a method of producing a Vertical Cavity Surface Emitting Laser is provided, comprising: providing a layer stack of semiconductor layers, the semiconductor layers of the layer stack including a first mirror, a second mirror, an active region between the first and second mirrors, an Al₁₋ₓGaₓAs-layer with 0≤x≤0.05, and a contact layer immediately adjacent to the Al₁₋ₓGaₓAs-layer; etching the layer stack to obtain a first layer sub-stack forming a mesa and a second layer sub-stack adjacent to the mesa in stacking direction of the layer stack, the layers of the second layer sub-stack extend beyond the layers of the first layer sub-stack in direction perpendicular to the stacking direction, and using the Al₁₋ₓGaₓAs-layer as an etch-stop layer; removing an outer part of the Al₁₋ₓGaₓAs-layer to expose in part the contact layer; oxidizing the Al₁₋ₓGaₓAs-layer to obtain an oxide aperture layer.

When the outer part of the AlAs-layer is removed to expose in part the contact layer, two important steps of the method are reached simultaneously: the remaining AlAs-layer in the mesa can now be oxidized to create the current aperture in the center of the mesa, and in addition the layer directly below the dual-functional AlAs-layer is now open outside the mesa tower. An advantage of the method is the exact targeting of the opening of the layer directly below the AlAs-layer. This is particularly advantageous, because the specific positioning of the contact layer is crucial for operation. For example, the specific position of the contact layer may be in a node of the standing wave field of the laser light in the resonator during operation of the VCSEL.

A metal or ohmic contact may be arranged on the exposed outer part of the contact layer in a further step.

Preferentially, the etching includes a selective etching process which automatically stops at the AlAs-layer.

The selective etching process may be a selective wet-chemical etching process. For example, selective wet-chemical-etching may be performed with NH₃:H₂O₂.

Further preferentially, the selective etching process may be preceded by an initial etching process, and further comprising stopping the initial etching process one or more layers apart from the AlAs-layer.

This measure has the advantage that the initial etching process may be performed using an etching process different from the selective etching process, and which is more suitable to obtain straight edges of the mesa during mesa formation. Since the initial etching process might not automatically stop at the AlAs-etch-stop layer, it is advantageous to stop the initial etching process one or more layers apart from the AlAs-layer. The outer parts of the one or more remaining layers still present above the AlAs-layer, e.g. AlGaAs/GaAs-based layers, are removed by the selective etching process which automatically stops at the AlAs-layer.

The initial etching process may be a dry etching process. Preferably, reactive ion etching (RIE) or inductively coupled plasma (ICP) etching processes are preferred as the dry etching process.

The layer stack of semiconductor layers may be provided by epitaxially growing semiconductor layers on a wafer or substrate. The substrate may be removed after the VCSEL is produced.

The VCSEL may be a top emitter or a bottom emitter.

It shall be understood that the VCSEL according to any embodiment described above and described below and the method of producing the VCSEL may have similar and/or identical embodiments. Further advantageous embodiments are defined below.

According to the principles described herein, a Vertical Cavity Surface Emitting Laser (VCSEL) comprises a dual-functional Al₁₋ₓGaₓAs layer with 0≤x≤0.05 which includes the case of an AlAs (aluminum arsenide) layer. In the following description and in the drawings, only the term AlAs-layer is used, which however does not exclude the case of an Al₁₋ₓGaₓAs layer with 0<x≤0.05.

The dual functionality of the AlAs-layer arises from using the AlAs-layer to provide an oxide aperture layer forming a current aperture on the one hand. On the other hand, the AlAs-layer is used as an etch-stop layer in the process of producing the VCSEL to ensure a precise control of the etching process. A precise control of the etching process in the process of producing the VCSEL is essential to target a thin layer immediately adjacent to the AlAs-layer, in particular if this adjacent layer is a contact layer for forming an intracavity contact.

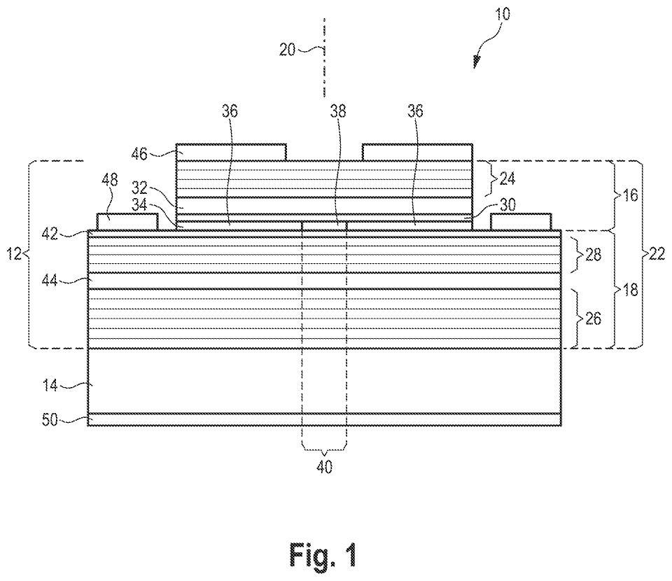

An embodiment of a VCSEL 10 which makes use of the principles of the present disclosure is shown in FIG. 1. It is to be understood that the principles of the present disclosure are not limited to the embodiment shown in FIG. 1, but can be used in all other VCSEL structures, in particular in all standard VCSEL structures.

The VCSEL 10 in FIG. 1 comprises a layer stack 12 of semiconductor layers. The layer stack 12 may be arranged on a substrate 14. The layer stack 12 comprises a first layer sub-stack 16 forming a mesa of the VCSEL 10. The layer stack 12 comprises a second layer sub-stack 18 which is immediately adjacent to the sub-stack 16 forming the mesa in stacking direction of the layer stack 12. In FIG. 1, the stacking direction of the layer stack 12 is illustrated by an axis 20. The semiconductor layers of the second sub-stack 18 extend beyond the semiconductor layers of the first sub-stack 16 (mesa) in direction perpendicular to the stacking direction 20, as shown in FIG. 1.

The semiconductor layers of the layer stack 12 form an optical resonator 22. The optical resonator 22 comprises a first mirror 24. The first mirror 24 may be configured as a distributed Bragg reflector (DBR). The first mirror 24 may comprise a plurality of semiconductor layer pairs based on the AlGaAs/GaAs material system, wherein the layer pairs have alternating high refractive index and low refractive index layers.

The optical resonator 20 further comprises a second mirror which is, in the embodiment shown, divided into three portions, a first portion 26, a second portion 28, and a third portion 30. The second mirror comprising the portions 26, 28, 30 may comprise a plurality of layer pairs with alternating high refractive and low refractive indices based on the AlGaAs/GaAs material system.

The optical resonator 22 further comprises an active region 32 which is arranged between the first mirror 24 and the second mirror comprising the portions 26, 28, 30. The active region 32 may comprise one or more quantum well layers, for example based on GaAs. The active region 32 is arranged to generate laser light with a wavelength of e.g. 850 nm (in air) or greater.

Further included in the layer stack 12 is an oxide aperture layer 34. The oxide aperture layer 34 comprises an oxidized outer region 36 which is electrically non-conducting, and a non-oxidized center region 38 which is electrically conducting. The oxide aperture layer 34 is based on AlAs, wherein the outer region 36 comprises an oxide of AlAs, e.g. AlₓO_{y}. The center region 38 comprises non-oxidized AlAs. The center region 38 forms an aperture 40 for current and optical confinement.

The optical resonator 22 further comprises a contact layer 42 which is immediately adjacent to the oxide aperture layer 34. While the oxide aperture layer 34 forms the last layer of the first sub-stack 16 forming the mesa, the contact layer 42 is the first layer of the second sub-stack of semiconductor layers. In order to function as a contact layer, the contact layer 42 has a doping concentration sufficient for ohmic behavior of the contact layer. The doping level of the contact layer 42 may be as high as 6×10¹⁸ cm⁻³ or higher. In case the contact layer 42 is a p-contact layer, the dopant may be carbon (C) or Zinc (Zn) or any other p-type dopant or even a combination of several of them. The contact layer 42 preferentially is a thin layer. As such, the thickness of the contact layer may be at least 10 nm, or at least 15 nm, for example about 20 nm.

The doping concentration in the contact layer 42 may gradually decrease in the thickness direction of the contact layer 42 from a side facing the oxide aperture layer 34 to the side facing the second portion of the second mirror 28. Alternatively, the doping concentration may be constant in the contact layer 42 if the contact layer 42 is thin, e.g. 10 nm, and the doping concentration may gradually decrease to a layer following this thin contact layer 42 on a side facing away from the oxide aperture layer 34.

In a preferred embodiment, the VCSEL 10 further may comprise an integrated photodiode comprising an intrinsic absorption region 44 which may comprise one or more intrinsic absorption and additional intrinsic layers. The photodiode absorption region 44 is embedded in the second mirror, here between the first and second portions 26, 28 of the second mirror. The first portion 26 has a different doping polarity than the second portion 28 so that the first and second portions 26, 28 form an np- or a pn-junction of the photodiode.

The VCSEL 10 further comprises a contact arrangement for driving the VCSEL 10. The electrical contact arrangement comprises a first electrical contact 46, here formed as a ring electrode which is arranged on the outer side of the first sub-stack 16 forming the mesa. The electrical contact arrangement further comprises a second electrical contact 48 configured as an intracavity contact. The electrical contact 48 is in contact with the contact layer 42. The electrical contact 48 is configured in the present embodiment as a ring electrode.

A third electrical contact 50 may be arranged on an outer side of the substrate 14. The first and second electrical contacts 46, 48 serve to drive the VCSEL 10 for laser emission. The electrical contacts 48 and 50 serve to drive the photodiode.

During operation of the VCSEL 10, the generated laser light forms a standing wave field within the resonator 22. The contact layer 42 is preferably arranged in a node of this standing wave field of laser light in the optical resonator 22 in order to reduce absorption losses to which the high doping level of the contact layer 42 might give rise. In this regard, a thin contact layer 42 arranged in a node of the standing wave field of the laser light in the optical resonator 22 is preferred.

Further, in the present embodiment, the oxide aperture layer 34 based on AlAs is spaced apart from the active region 32 by the third portion 30 of the second mirror. The third portion 30 may comprise one or more mirror pairs, e.g. one to five mirror pairs. A separation of the oxide aperture layer 34 from the active region 32 by one or more layers may drop the efficiency of the current confinement provided by the oxide aperture layer 34, but also the optical guiding. The latter leads to a smaller numerical aperture (NA), which is beneficial in VCSELs with integrated photodiodes (ViPs).

In the present embodiment, the VCSEL 10 is a ViP. The ViP may be an npn-ViP, or a pnp-ViP. Preferentially, the VCSEL 10 is an npn-ViP. In this case, the electrical contact 46 is an n-contact, and the first mirror 24 is an n-mirror. The second and third portions 28, 30 of the second mirror are p-doped, and the first portion 26 of the second mirror is n-doped. The intracavity contact 48 is a p-contact, and the contact layer 42 is a p-contact layer, accordingly. The bottom contact 50 is an n-contact. For a pnp-ViP, the polarities described above are reversed, accordingly.

Thus, the ViP only has two pn-junctions, thus dispensing with one parasitic pn-junction as in conventional ViPs.

The contact layer 42 may be a GaAs-layer.

The VCSEL may be a top emitter, wherein the reflectivity of the first mirror 24 is slightly reduced in comparison with the reflectivity of the second mirror so that the first mirror 24 serves as an out-coupling mirror. In other embodiments (not shown), the VCSEL 10 may be configured as a bottom emitter, wherein the reflectivity of the second mirror then is slightly reduced in comparison with the first mirror 24. For a bottom emitter, the bottom contact 50 may be configured as a ring electrode to allow laser light to exit through the aperture of the bottom electrode. In further embodiments (not shown), the substrate 14 may be removed.

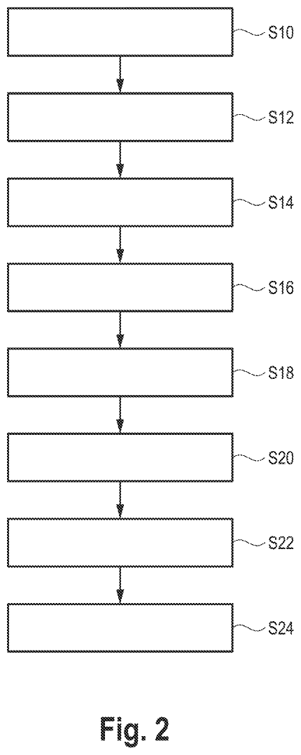

In the following, an embodiment of a method of producing a VCSEL will be described with reference to FIGS. 2 to 6. For the sake of simplicity, the method of producing a VCSEL will be described based on the VCSEL 10 in FIG. 1.

According to the principles of the present disclosure, an AlAs-layer incorporated into the epitaxial stack is used with dual functionality, namely on the one hand to provide an oxide aperture layer, and on the other hand, to provide an etch-stop layer in the process of producing the VCSEL.

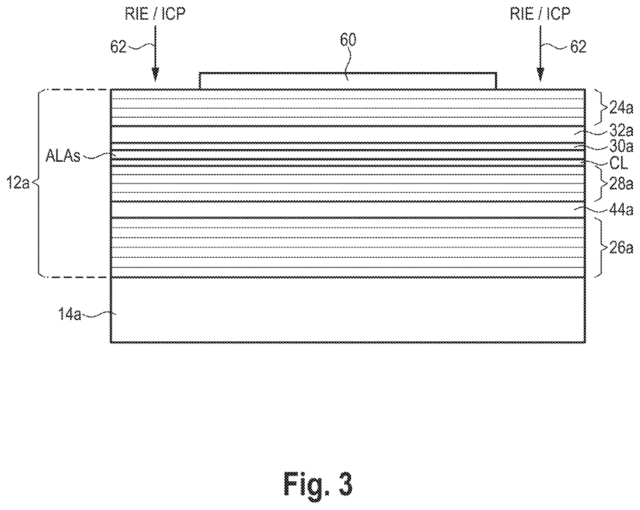

According to FIG. 2, the method may begin at S10. At S10, a layer stack 12a is provided as shown in FIG. 3. The layer stack 12a may be provided on a substrate or wafer 14a. The semiconductor layers of layer stack 12a include layers 24a of a first mirror, one or more layers 32a of an active region, one or more layers 30a of a third portion of a second mirror, an aluminum-arsenide layer ‘AlAs’, a contact layer CL, layers 28a of a second portion of a second mirror, one or more layers 44a of an absorption region of a photodiode, layers 26a of a first portion of the second mirror.

The afore-mentioned layers may have been epitaxially grown on the substrate 14a.

At S12 in FIG. 2, and further with reference to FIG. 3, the subsequent etching process to obtain a mesa is prepared by covering the upper surface of the layer stack 12a with photoresist 60 in a region of the layer stack 12a where the mesa is to be formed.

Next, the layer stack 12a is etched to gradually form the mesa. Preferentially, the etching process is divided into two successive etching processes, an initial etching process and a subsequent etching process.

At S14 in FIG. 2 and with continued reference to FIG. 3, the initial etching process is performed using a dry etching process. For example, dry etching may be performed with reactive ion etching (ME) or inductively coupled plasma (ICP) etching. These etching processes are advantageous as they are suitable to obtain straight edges of the mesa to be formed. In FIG. 3, the initial etching process is illustrated by arrows 62.

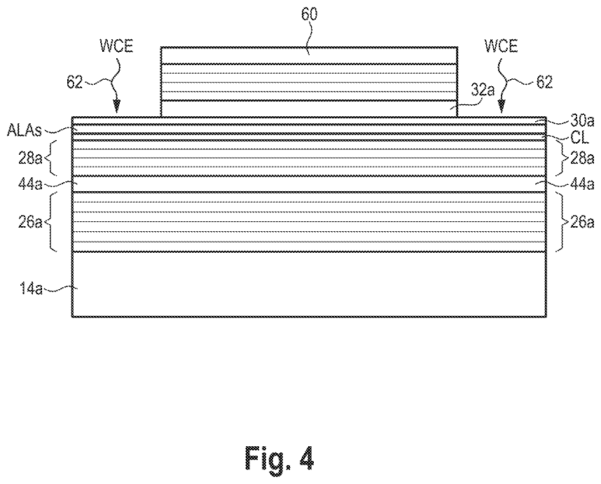

At S16 in FIG. 2 and as shown in FIG. 4, the initial etching process is stopped one or more layers before the initial etching process reaches the AlAs-layer. When the initial etching process is stopped, a part of a first sub-stack of semiconductor layers and thus a part of a mesa is formed. For example, the initial etching process may be stopped when the etching reaches a layer of the third portion 30a of the second mirror, above the AlAs-layer.

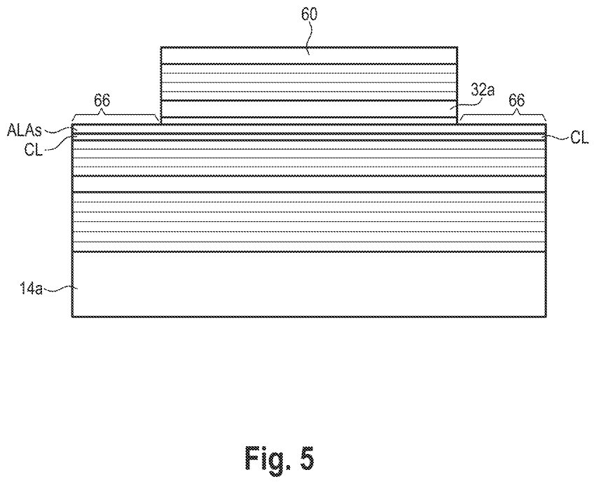

At S18 in FIG. 2 and as shown in FIG. 4, etching the layer stack 12a is continued by a selective etching process, in particular a selective wet-chemical etching process (WCE) as illustrated in FIG. 4 by arrows 64. The selective wet-chemical etching process is chosen to stop automatically when reaching the AlAs-layer. The selective etching process removes the remaining semiconductor layers, e.g. AlGaAs/GaAs-based layers of the third portion 30a of the second mirror above the AlAs-layer. A suitable etching agent for selective wet-chemical etching is, for example NH₃:H₂O₂ (pH 8.3). FIG. 5 shows the stage of the method when the selective etching process has automatically stopped at the AlAs-layer. Instead of a wet-chemical etching process, a selective dry chemical etching process, in particular without physical component, may be used.

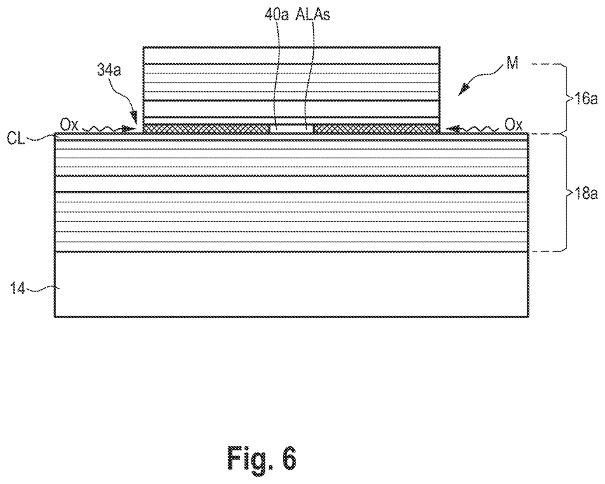

Subsequently, at S20 in FIG. 2 and as shown in FIG. 6, an outer part 66 of the AlAs-layer is removed, which can be performed by etching with, e.g. HF:H₂O or HCl:H₂O. The mesa is now readily obtained, with the remaining inner part of the AlAs layer forming the lowermost layer of the mesa.

By removing the outer part 64 of the AlAs-layer, two important steps are reached simultaneously: The remaining AlAs-layer which is included in the mesa, can now be oxidized at S22 to create the current aperture 40a in the center of the mesa, plus the contact layer directly adjacent to the dual-functional AlAs-layer is now open outside the mesa tower. The advantage of the method according to the principles of the present disclosure thus is the exact targeting of the opening of the layer, here the contact layer CL, directly below the oxide aperture. This is particular advantageous for the contact layer CL, as the specific positioning of the contact layer CL is crucial for reliable operation of the VCSEL.

In FIG. 6, the oxidizing process is illustrated by “Ox” and the crosses in the AlAs-layer illustrate the oxidized outer region of the current aperture layer 34a obtained in this way. As shown in FIG. 6, the photoresist 60 is removed.

At S24 in FIG. 2, electrical contacts like electrical contacts 46, 48 and 50 shown in FIG. 1 may be provided on the layer stack 12a.

When the VCSEL according to the present disclosure is configured as ViP, it may be used in sensors, such as sensor for gesture control, velocity and distance measurement, particle density measurement, 3D-cameras, etc., in particular in sensing applications based on self-mixing interference.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A Vertical Cavity Surface Emitting Laser, comprising:
a layer stack of semiconductor layers, the layer stack including:
a first layer sub-stack forming a mesa, and
a second layer sub-stack adjacent to the mesa in a stacking direction of the layer stack, wherein layers of the second layer sub-stack extend beyond layers of the first sub-stack in a direction perpendicular to the stacking direction,
wherein the semiconductor layers of the layer stack form an optical resonator having a first mirror, a second mirror, an active region between the first and second mirrors for laser light generation, and an oxide aperture layer forming a current aperture,
wherein the oxide aperture layer is made from Al₁₋ₓGaₓAs with 0≤x≤0.05,
wherein the oxide aperture layer is a last layer of the mesa and immediately adjacent to a first layer of the second layer sub-stack, and
wherein a first layer of the second layer sub-stack is a contact layer.

2. The Vertical Cavity Surface Emitting Laser of claim 1, wherein the contact layer is arranged in a node of a standing wave field of laser light in the optical resonator.

3. The Vertical Cavity Surface Emitting Laser of claim 1, wherein the contact layer has a doping concentration sufficient for ohmic behavior of the contact layer.

4. The Vertical Cavity Surface Emitting Laser of claim 3, wherein the doping concentration in the contact layer gradually decreases in a thickness direction of the contact layer from a side facing the oxide aperture layer to an opposite side, or
wherein the doping concentration gradually decreases from the contact layer to an adjacent layer on a side of the contact layer facing away from the oxide aperture layer.

5. The Vertical Cavity Surface Emitting Laser of claim 1, wherein the contact layer has a thickness of at least 10 nm.

6. The Vertical Cavity Surface Emitting Laser of claim 1, wherein the contact layer is a p-doped contact layer.

7. The Vertical Cavity Surface Emitting Laser of claim 1, further comprising a photodiode having an intrinsic absorption region integrated into the first mirror and/or the second mirror.

8. The Vertical Cavity Surface Emitting Laser of claim 7, wherein the second mirror has a first portion facing the contact layer, which is a p-doped region of the layer stack, and a second portion facing away from the contact layer, which is an n-doped region of the layer stack, wherein the intrinsic absorption region of the photodiode is arranged between the first and second portions of the second mirror.

9. The Vertical Cavity Surface Emitting Laser of claim 1, wherein the first mirror is an n-doped region of the layer stack.

10. The Vertical Cavity Surface Emitting Laser of claim 1, wherein at least one mirror layer pair of the second mirror is arranged between the active region and the oxide aperture layer.

11. A method of producing a Vertical Cavity Surface Emitting Laser, the method comprising:
providing a layer stack of semiconductor layers, the semiconductor layers of the layer stack including a first mirror, a second mirror, an active region between the first and second mirrors, an Al₁₋ₓGaₓAs layer with 0≤x≤0.05, and a contact layer immediately adjacent to the Al₁₋ₓGaₓAs layer;
etching the layer stack to obtain a first layer sub-stack forming a mesa and a second layer sub-stack adjacent to the mesa in a stacking direction of the layer stack, wherein layers of the second layer sub-stack extend beyond layers of the first layer sub-stack in a direction perpendicular to the stacking direction, and wherein the Al₁₋ₓGaₓAs layer is used as an etch-stop layer;
removing an outer part of the Al₁₋ₓGaₓAs layer to expose, at least in part, the contact layer; and
oxidizing the Al₁₋ₓGaₓAs layer to obtain an oxide aperture layer.

12. The method of claim 11, wherein the etching includes a selective etching process which automatically stops at the Al₁₋ₓGaₓAs layer.

13. The method of claim 12, wherein the selective etching process is a selective wet-chemical or a dry chemical etching process.

14. The method of claim 12, wherein the selective etching process is preceded by an initial etching process, the method further comprising stopping the initial etching process one or more layers apart from the Al₁₋ₓGaₓAs layer.

15. The method of claim 14, wherein the initial etching process is a dry etching process.
